(19) United States
(12) Patent Application Publication
(10) Pub. No.: US 2007/0147454 A1
(43) Pub. Date: Jun. 28, 2007

(54) LIGHT EMITTING DEVICE

(76) Inventors: Wei LIN, Yung-Kang City ,Tainan Hsien (TW); Yu-Huei WU, Yung-Kang City ,Tainan Hsien (TW); Rong-Tay HSU, Yung-Kang City ,Tainan Hsien (TW)

Correspondence Address: OSTROLENK FABER GERB & SOFFEN, 1180 AVENUE OF THE AMERICAS, NEW YORK, NY, 100368403, US

(21) Appl. No.: 11/457,970

(22) Filed: Jul. 17, 2006

(30) Foreign Application Priority Data
Dec. 28, 2005 (TW) 094147011

(51) Int. Cl. H01S 5/00; H01S 3/04

(52) U.S. Cl. 372/45.01; 372/43.01; 372/44.01

(57) ABSTRACT

A light emitting device includes an active region of a multiple-quantum-well layered structure including a plurality of quantum well layers of InₓGa₁₋ₓAs_{y}P_{1-y}, where x=0.1 to 1.0, and y=0.0 to 1.0, and a barrier unit including a plurality of first barrier layers alternating with the quantum well layers, and at least one second barrier layer of AlᵤGaᵥIn₁₋ᵤ₋ᵥAs, where u=0.3 to 1.0, and v=0.0 to 0.7.

### BACKGROUND OF THE INVENTION

1. Field of the Invention

This invention relates to a light emitting device, more particular to a light emitting device including multiple quantum well layers of InₓGa₁₋ₓAs_{y}P_{1-y}, and at least one barrier layer of AlᵤGaᵥIn₁₋ᵤ₋ᵥAs.

2. Description of the Related Art

FIG. 1 illustrates energy band profiles of a laser diode of a conventional light emitting device that includes an InAlGaAs based active region 1 sandwiched between a pair of separate confinement heterostructures 100. The InAlGaAs based active region 1 includes multiple quantum well layers 11 and barrier layers 12 alternating with the quantum well layers 11. The InAlGaAs based active region of the conventional light emitting device has a conduction band energy difference between each barrier layer 12 and an adjacent one of the quantum well layers 11 within 200 to 235 meV.

FIG. 2 illustrates energy band profiles of a laser diode of another conventional light emitting device that includes an InAlGaAs based active region 2 sandwiched between a pair of separate confinement heterostructures 200. The InAlGaAs active region includes a multiple quantum well structure of quantum well layers 21, and a barrier unit having barrier layers 23 alternating with the quantum well layers 21, and an electron reflector 22, which also serves as an energy barrier, formed on an endmost one of the barrier layers 23. The electron reflector 22 has a conduction band energy much greater than those of the barrier layers 23, thereby enhancing the conduction band energy difference between the barrier unit and the multiple quantum well structure. However, the electron reflector 22 of the InAlGaAs based active region 2 of the conventional light emitting device has a relatively low valence band energy such that the difference in the valence band energy between the electron reflector 22 and an adjacent barrier layer 23 is relatively large (i.e., greater than 100 meV). As a consequence, movement of electron holes into the multiple quantum well structure is considerably hindered.

### SUMMARY OF THE INVENTION

Therefore, the object of the present invention is to provide a light emitting device including an active region having at least one barrier layer that has a higher conduction band energy as compared to those of the quantum well layers of the aforesaid conventional light emitting devices, and that has a valence band energy approximating to those of other barrier layers of the active region.

According to the present invention, there is provided a light emitting device that comprises an active region of a multiple-quantum-well layered structure including a plurality of quantum well layers of InₓGa₁₋ₓAs_{y}P_{1-y}, where x=0.1 to 1.0, and y=0.0 to 1.0, and a barrier unit including a plurality of first barrier layers alternating with the quantum well layers, and at least one second barrier layer of AlᵤGaᵥIn₁₋ᵤ₋ᵥAs where u=0.3 to 1.0, and v=0.0 to 0.7.

### BRIEF DESCRIPTION OF THE DRAWINGS

In drawings which illustrate embodiments of the invention,

FIG. 1 is a schematic view showing the structure of a conventional light emitting device in accordance with energy band profiles of the conventional light emitting device;

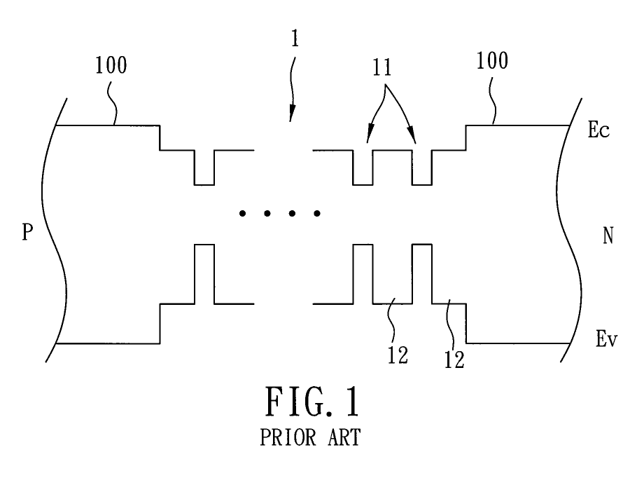

FIG. 2 is a schematic view showing the structure of another conventional light emitting device in accordance with energy band profiles of the conventional light emitting device;

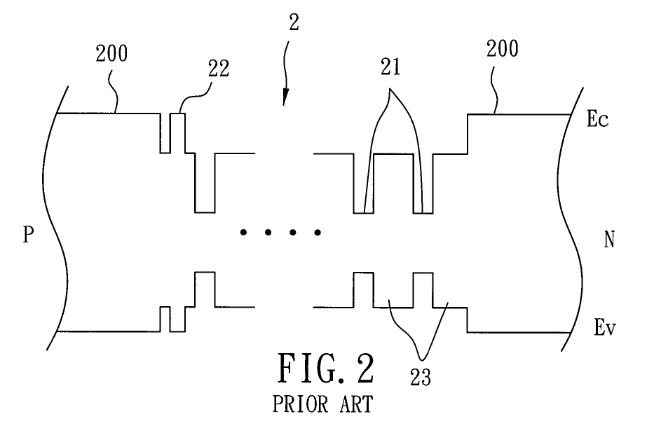

FIG. 3A is a schematic view of the first preferred embodiment of a light emitting device according to this invention;

FIG. 3B is a schematic view of the first preferred embodiment, showing the structure of the light emitting device in accordance with energy band profiles of the light emitting device;

FIG. 4 is a schematic view illustrating the general structure of one of repeated basic units of an active region of the light emitting device of this invention;

FIG. 5 is a diagram showing a design scheme on how the compositions of the semiconductor materials of the quantum well layers and the barrier layers of the light emitting device of this invention are determined using the basic unit shown in FIG. 4;

FIG. 6 is a schematic view showing the results of the conduction energy difference between a barrier layer and an adjacent barrier layer and the valence band energy difference between the adjacent barrier layer and an adjacent quantum well layer of the light emitting device of this invention obtained from the design scheme shown in FIG. 5;

FIG. 7A is a schematic view of the second preferred embodiment of the light emitting device according to this invention;

FIG. 7B is a schematic view of the second preferred embodiment, showing the structure of the light emitting device in accordance with energy band profiles of the light emitting device;

FIG. 8A is a schematic view of the third preferred embodiment of the light emitting device according to this invention; and

FIG. 8B is a schematic view of the third preferred embodiment, showing the structure of the light emitting device in accordance with energy band profiles of the light emitting device.

### DETAILED DESCRIPTION OF THE PREFERRED EMBODIMENTS

Before the present invention is described in greater detail, it should be noted that same reference numerals have been used to denote like elements throughout the specification.

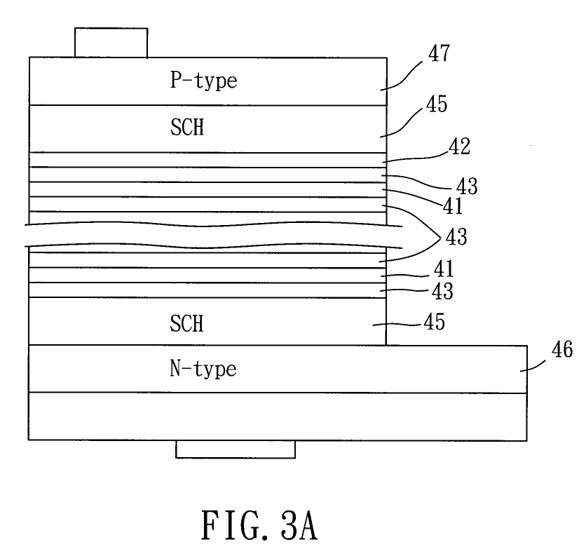

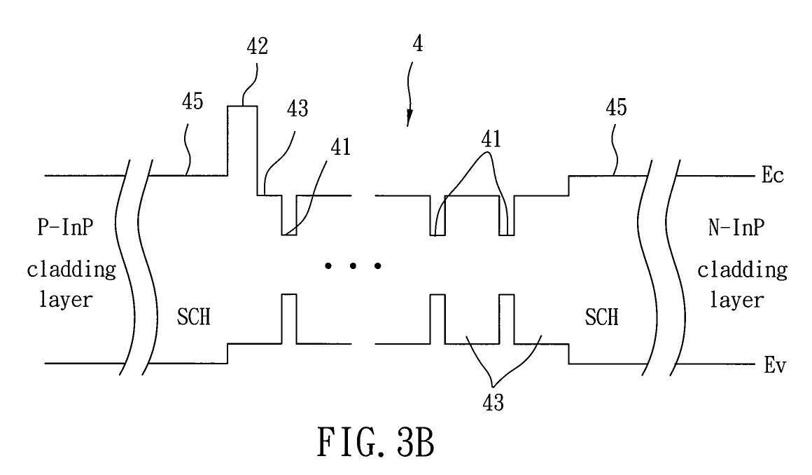

FIGS. 3A and 3B illustrate the first preferred embodiment of a light emitting device according to this invention. The light emitting device includes an active region 4 of a multiple-quantum-well (MQW) layered structure including a plurality of quantum well layers 41 of InₓGa₁₋ₓAs_{y}P_{1-y}, where x=0.1 to 1.0, and y=0.0 to 1.0, and a barrier unit including a plurality of first barrier layers 43 alternating with the quantum well layers 41, and at least one second barrier layer 42 of AlᵤGaᵥIn₁₋ᵤ₋ᵥAs, where u=0.3 to 1.0, and v=0.0 to 0.7. Note that the second barrier layer 42 serves as an electron reflector for raising the energy barrier for the MQW layered structure. Hence, the second barrier layer 42 is hereinafter also referred to as the electron reflector in the following paragraphs.

In this embodiment, each of the first barrier layers 43 is made from InₘGa₁₋ₘAsₙP₁₋ₙ, where m=0.1 to 1.0, and n=0.0 to 1.0. The electron reflector 42 is formed on an endmost one of the first barrier layers 43.

The light emitting device further includes first and second separate confinement heterostructures (SCH) of InGaAsP 45 sandwiching the active region 4 therebetween, and n-type and p-type cladding layers 46, 47 of InP. The electron reflector 42 is sandwiched between the first SCH 45 and the endmost one of the first barrier layers 43. The second SCH 45 is formed on the other endmost one of the first barrier layers 43. The p-type cladding layer 47 is formed on the first SCH 45. The n-type cladding layer 46 is formed on the second SCH 46. First and second electrodes on opposite ends of the light emitting device are coupled to the n-type cladding layer 46 and the p-type cladding layer 47.

Preferably, the valence band energy difference between the electron reflector 42 and the endmost one of the first barrier layers 43 is within a range of from −10 to +10 meV. More preferably, the valence band energy difference between the electron reflector 42 and the endmost one of the first barrier layers 43 is within a range of from 0 to +10 meV. Preferably, the conduction band energy difference between the electron reflector 42 and the endmost one of the first barrier layers 43 is greater than 300 meV.

In the first preferred embodiment, the valence band energy difference between the electron reflector 42 and the endmost one of the first barrier layers 41 is approximately to zero.

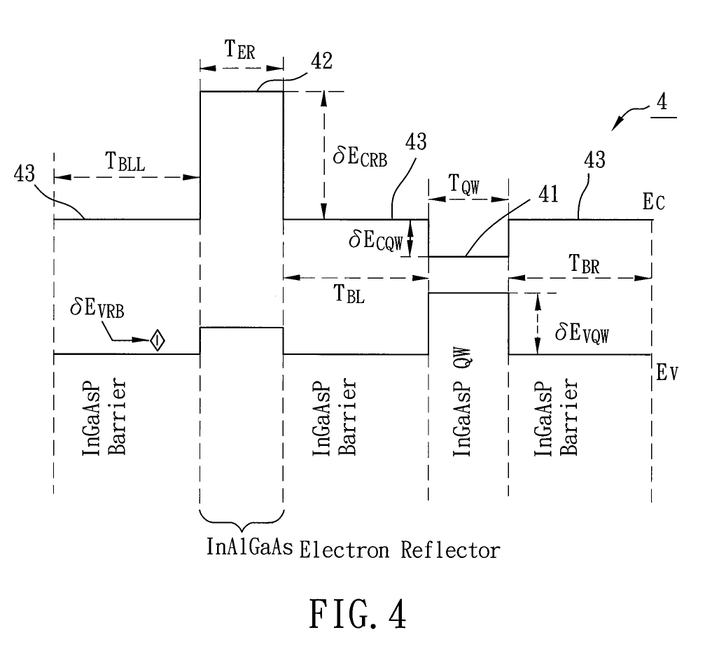

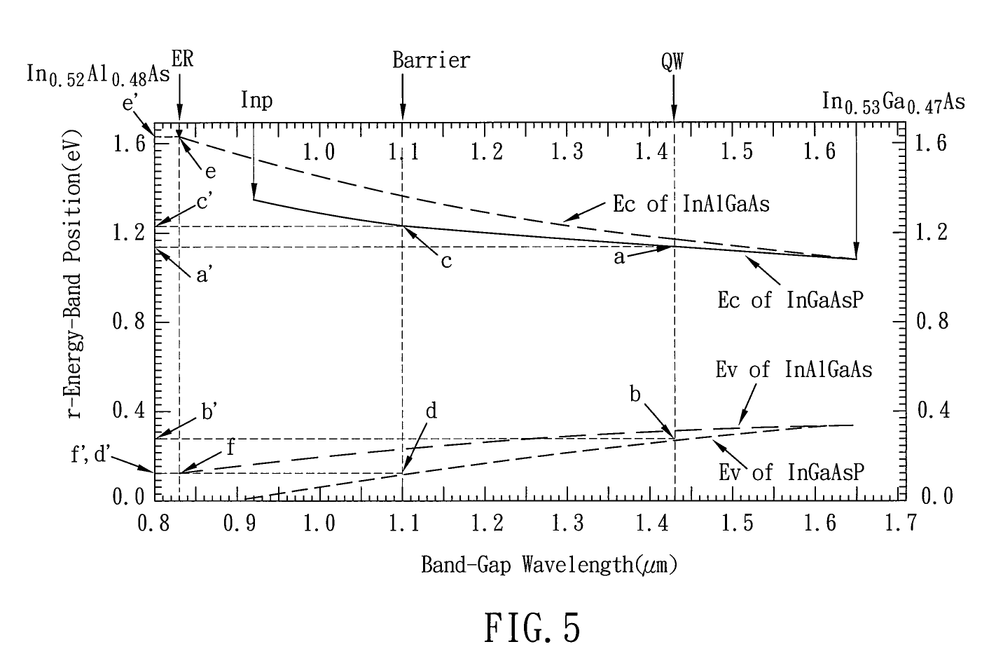

The compositions of the semiconductor materials used for the quantum well layers 41, the first barrier layers 43, and the electron reflector 42 of the active region 4 of the light emitting device are determined based on a design scheme illustrated in the following paragraphs with reference to FIGS. 4 and 5. In the design scheme, the active region 4 is represented as having repeated basic units of a general structure shown in FIG. 4. The general structure of each basic unit includes one quantum well layer 41, one electron reflector 42, and three first barrier layers 43. The quantum well layer 41 is sandwiched between two adjacent ones of the first barrier layers 43. The electron reflector 42 is sandwiched between two adjacent ones of the first barrier layers 43. With InₓGa₁₋ₓAs_{y}P_{1-y}, where x=0.1 to 1.0, and y=0.0 to 1.0, as the material for the first barrier layer 43 and for the quantum well layer 41, the designable span of the lattice mismatch of the first barrier layer 43 ranges from −15000 to +15000 ppm. With AlᵤGaᵥIn₁₋ᵤ₋ᵥAs, where u=0.3 to 1.0, and v=0.0 to 0.7 as the material for the electron reflector 42, the designable span of the lattice mismatch of the first barrier layer 43 ranges from −25000 to +12000 ppm. The active region 4 of the light emitting device is capable emitting a laser light of a wavelength ranging from 900 to 1850 nm.

In FIG. 4, the reference numeral T_{BLL} represents the thickness of the first barrier layer 43 disposed on the left side of the electron reflector 42, which ranges from 0 to 100 nm; T_{ER} represents the thickness of the electron reflector 42, which ranges from 1 to 100 nm; T_{BL} represents the thickness of the first barrier layer 43 disposed on the left side of the quantum well layer 41, which ranges from 0 to 100 nm; T_{QW} represents the thickness of the quantum well layer 41, which ranges from 0.6 to 35 nm; T_{BR} represents the thickness of the first barrier layer 43 disposed on the right side of the quantum well layer 41, which ranges from 0 to 100 nm; δ E_{VRB} represents the valence band energy difference between the electron reflector 42 and the first barrier layer 43; δ E_{CRB} represents the conduction band energy difference between the electron reflector 42 and the first barrier layer 43; δ E_{CQW} represents the conduction band energy difference between the first barrier layer 43 and the quantum well layer 41; and δ E_{VQW} represents the valence band energy difference between the first barrier layer 43 and the quantum well layer 41.

The curves (E_{c}_{_{—}}InAlGaAs, E_{c}_{_{—}}InGaAsP, Eᵥ_{_{—}}InAlGaAs, and Eᵥ_{_{—}}InGaAsP) shown in the diagram of FIG. 5 represent the relationship between the band-gap wavelength (λ_{g}, μm) and the energy band position (eV) for the conduction band energy and the valence band energy of the materials of InₓGa₁₋ₓAs_{y}P_{1-y} and AlᵤGaᵥIn₁₋ᵤ₋ᵥAs.

The following consecutive steps in the design scheme describe how the compositions of the quantum well layer 41, the electron reflector 42, and the first barrier layer 43 of each basic unit of the active region 4 are determined.
(a) determining the desired λ_{g} for the quantum well layer 41 of InGaAsP (for example, λ_{g}=1.43 μm, i.e., the composition for the quantum well layer 41 is In_{0.643}Ga_{0.357}As_{0.769}P_{0.231}), and starting from the point where λ_{g}=1.43 μm, drawing a vertical line that intersects the curve E_{c}_{_{—}}InGaAsP at point ‘a’ and the curve Eᵥ_{_{—}}InGaAsP at point ‘b’;
(b) determining the desired λ_{g} for the first barrier layer 43 of InGaAsP (for example, λ_{g}=1.1 μm, i.e., the composition for the first barrier layer 43 is In_{0.85}Ga_{0.15}As_{0.327}P_{0.673}), and starting from the point where λ_{g}=1.1 μm, drawing a vertical line that intersects the curve E_{c}_{_{—}}InGaAsP at point ‘c’ and the curve Eᵥ_{_{—}}InGaAsP at point ‘d’;
(c) starting from point ‘d’, drawing a horizontal line that intersects the curve Eᵥ_{_{—}}InAlGaAs at point ‘f’ where λ_{g}=0.83 μm, i.e., the composition for the electron reflector 42 is In_{0.52}Al_{0.48}As; and
(d) starting from point ‘f’, drawing a vertical line that intersects the curve E_{c}_{_{—}}InAlGaAs at point ‘e’.

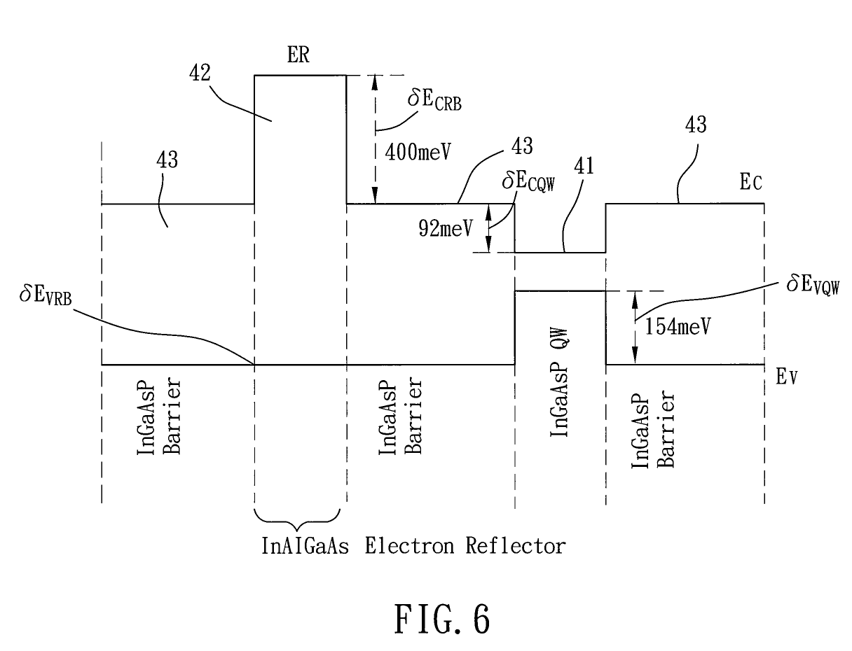

As illustrated in FIG. 6, in combination with FIG. 5, the MQW layered structure of the active region 4 thus formed has the λ E_{VRB} equal to zero meV (the difference is represented by the distance between point ‘d′’ and point ‘f′’ in FIG. 5), the λ E_{CRB} equal to 400 meV (the difference is represented by the distance between point ‘e′’ and ‘c′’ in FIG. 5), the λ E_{CQW} equal to 92 meV (the difference is represented by the distance between point ‘c′’ and point ‘a′’ in FIG. 5), and the λ E_{VQW} equal to 154 meV (the difference is represented by the distance between point ‘b′’ and point ‘d′’ in FIG. 5).

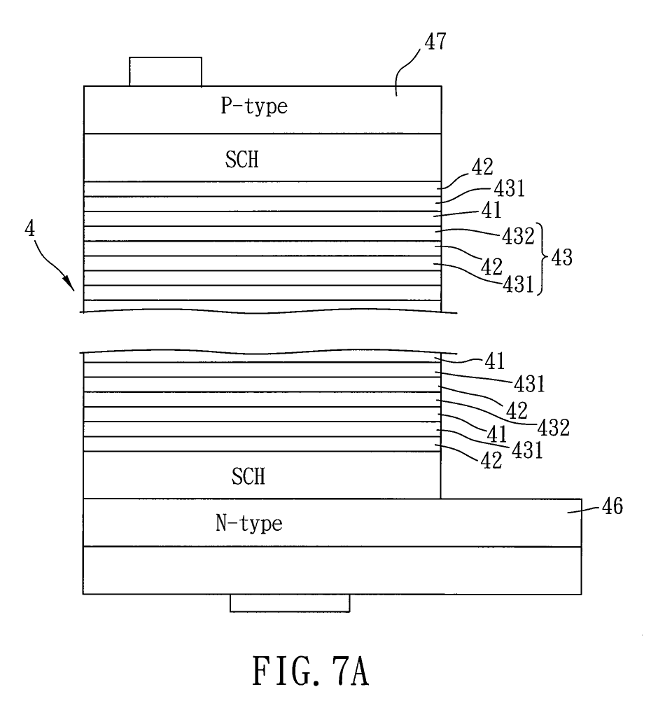

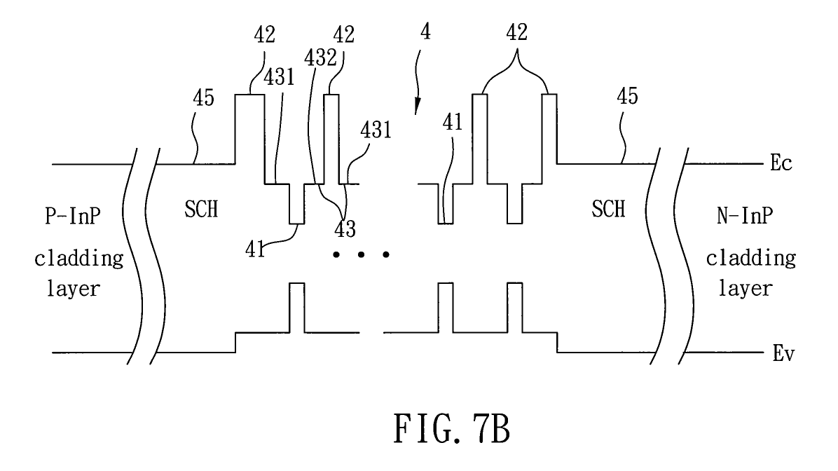

FIGS. 7A and 7B illustrate the second preferred embodiment of the light emitting device according to this invention. The light emitting device of this embodiment differs from the previous embodiment in that the barrier unit includes a plurality of the second barrier layers 42. Each of the first barrier layers 43 has first and second sub-layers 431, 432 sandwiching a respective one of the second barrier layers 42 therebetween. The first SCH 45 is formed on an endmost one of the second barrier layers 42, and the second SCH 45 is formed on the other endmost one of the second barrier layers 42.

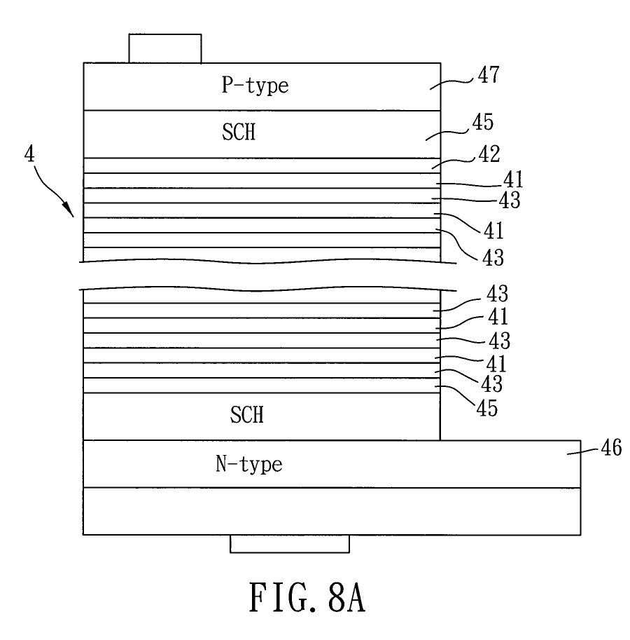

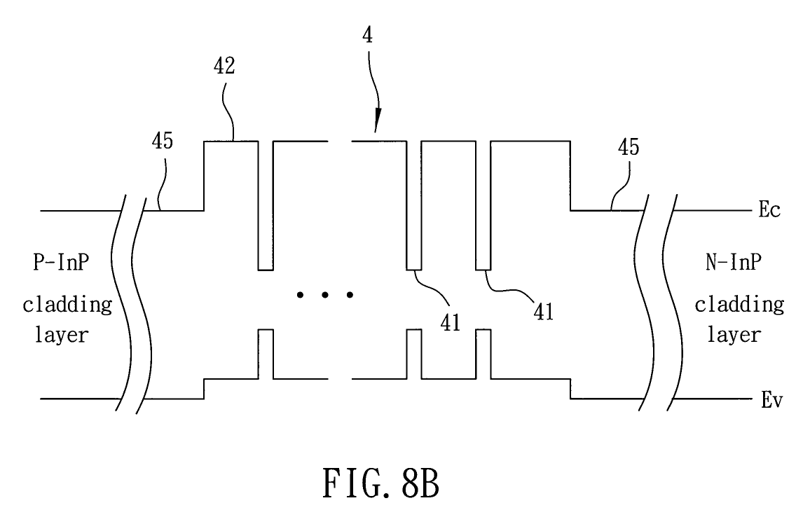

FIGS. 8A and 8B illustrate the third preferred embodiment of the light emitting device according to this invention. The light emitting device of this embodiment differs from the first preferred embodiment in that each of the first barrier layers 43 is made from AlᵤGaᵥIn₁₋ᵤ₋ᵥAs, which is the same as that of the second barrier layer 42. The second barrier layer 42 is formed on an endmost one of the first barrier layers 43. The second SCH 45 is formed on the other endmost one of the first barrier layers 43.

By selecting InₓGa₁₋ₓAs_{y}P_{1-y} as the material for the first barrier layer 43 and for the quantum well layer 41, and AlᵤGaᵥIn₁₋ᵤ₋ᵥAs as the material for the second barrier layer(s) or the electron reflector(s) 42 of the active region 4 of the light emitting device of this invention, the conduction band energy difference between the barrier unit and each quantum well layer 41 of the active region 4 can be raised to an extent greater than 400 meV, which is much higher than those (200 to 235 meV) of the aforesaid conventional light emitting devices, and the valence band energy difference between the electron reflector 42 and the adjacent first barrier layer 43 can be reduced to an extent within −10 to +10 meV, which is relatively low as compared to those of the aforesaid conventional light emitting devices.

With the invention thus explained, it is apparent that various modifications and variations can be made without departing from the spirit of the present invention.

What is claimed is:

1. A light emitting device comprising:
an active region of a multiple-quantum-well layered structure including
a plurality of quantum well layers of InₓGa₁₋ₓAs_{y}P_{1-y}, where x=0.1 to 1.0, and y=0.0 to 1.0, and
a barrier unit including a plurality of first barrier layers alternating with said quantum well layers, and at least one second barrier layer of AlᵤGaᵥIn₁₋ᵤ₋ᵥAs, where u=0.3 to 1.0, and v=0.0 to 0.7.

2. The light emitting device of claim 1, wherein each of said first barrier layers is made from InₘGa₁₋ₘAsₙP₁₋ₙ, where m=0.1 to 1.0, and n=0.0 to 1.0, said second barrier layer being formed on an endmost one of said first barrier layers, the valence band energy difference between said second barrier layer and said endmost one of said first barrier layers being within a range of from −10 to +10 meV.

3. The light emitting device of claim 2, wherein the valence band energy difference between said second barrier layer and said endmost one of said first barrier layers is within a range of from 0 to +10 meV.

4. The light emitting device of claim 2, wherein the conduction band energy difference between said second barrier layer and said endmost one of said first barrier layers is greater than 300 meV.

5. The light emitting device of claim 2, further comprising first and second separate confinement heterostructures of InGaAsP sandwiching said active region therebetween, said second barrier layer being sandwiched between said first separate confinement heterostructure and said endmost one of said first barrier layers, said second separate confinement heterostructure being formed on the other endmost one of said first barrier layers.

6. The light emitting device of claim 5, further comprising a p-type cladding layer of InP formed on said first separate confinement heterostructure, and an n-type cladding layer of InP formed on said second separate confinement heterostructure.

7. The light emitting device of claim 1, wherein said barrier unit includes a plurality of said second barrier layers, each of said first barrier layers being made from InₘGa₁₋ₘAsₙP₁₋ₙ, where m=0.1 to 1.0, and n=0.0 to 1.0, and having first and second sub-layers sandwiching a respective one of said second barrier layers therebetween.

8. The light emitting device of claim 7, wherein the valence band energy difference between each of said second barrier layers and an adjacent one of said first barrier layers is within a range of from −10 to +10 meV.

9. The light emitting device of claim 7, wherein the valence band energy difference between each of said second barrier layers and an adjacent one of said first barrier layers is within a range of from 0 to +10 meV.

10. The light emitting device of claim 7, wherein the conduction band energy difference between each of said second barrier layers and an adjacent one of said first barrier layers is greater than 300 eV.

11. The light emitting device of claim 7, further comprising first and second separate confinement heterostructures of InGaAsP sandwiching said active region therebetween, said first separate confinement heterostructure being formed on an endmost one of said second barrier layers, said second separate confinement heterostructure being formed on the other endmost one of said second barrier layers.

12. The light emitting device of claim 11, further comprising a p-type cladding layer of InP formed on said first separate confinement heterostructure, and an n-type cladding layer of InP formed on said second separate confinement heterostructure.

13. The light emitting device of claim 1, wherein each of said first barrier layers is made from AlᵤGaᵥIn₁₋ᵤ₋ᵥAs, said second barrier layer being formed on an endmost one of said first barrier layers.

14. The light emitting device of claim 13, further comprising first and second separate confinement heterostructures of InGaAsP sandwiching said active region therebetween, said first separate confinement heterostructure being formed on said second barrier layer, said second separate confinement heterostructure being formed on the other endmost one of said first barrier layers.

15. The light emitting device of claim 14, further comprising a p-type cladding layer of InP formed on said first separate confinement heterostructure, and an n-type cladding layer of InP formed on said second separate confinement heterostructure.
